(19) United States
(12) Patent Application Publication
(10) Pub. No.: US 2019/0019457 A1
(43) Pub. Date: Jan. 17, 2019

(54) DISPLAY DEVICE AND METHOD OF DRIVING THE SAME

(71) Applicant: Shenzhen China Star Optoelectronics Semiconductor Display Technology Co., Ltd., Shenzhen, Guangdong (CN)

(72) Inventors: Bobiao Chang, Shenzhen, Guangdong (CN); Shu Wen, Shenzhen, Guangdong (CN); Yi-chien Wen, Shenzhen, Guangdong (CN); Ming-jong Jou, Shenzhen, Guangdong (CN)

(21) Appl. No.: 15/741,153

(22) PCT Filed: Oct. 18, 2017
(86) PCT No.: PCT/CN2017/106681

§ 371 Date: Dec. 29, 2017

(30) Foreign Application Priority Data
Jul. 11, 2017 (CN) 201710562316.3

(51) Int. Cl. G09G 3/3258; H01L 51/52; H01L 27/32

(52) U.S. Cl. CPC G09G 3/3258; G09G 2310/0264; H01L 27/3276; H01L 51/5203

(57) ABSTRACT

A display device includes: a plurality of pixels each including an organic light emitting diode, a power voltage supply supplying a power positive voltage and a power negative voltage to the plurality of pixels, a voltage detector generating a compensation signal when detecting that the power positive voltage and a standard power positive voltage are different, a timing controller compensating a scan control signal and a data control signal based on the compensation signal, a scan driver generating a compensated scan voltage based on a compensated scan control signal and supplying the compensated scan voltage to the plurality of pixels and a data driver generating a compensated data voltage based on a compensated data control signal and supplying the compensated data voltage to the plurality of pixels, wherein the compensated scan voltage and the compensated data voltage allow a driving current of the organic light emitting diode to be constant.

### TECHNICAL FIELD

The present disclosure relates to a field of display technology, and in particularly, relates to a display device and a method of driving the same.

### BACKGROUND ART

In recent years, an Organic Light Emitting Diode (OLED) display becomes a newly-developing flat panel display which is very popular around the world, due to its characteristics such as self-luminous, wide viewing angle, short response time, high luminous efficiency, wide color gamut, thin thickness, capable of being made to be a large size and flexible display, simple manufacturing processes, etc. Moreover, it has a potential of being low cost.

The existing OLED display can be divided into a passive matrix OLED (PMOLED) and an active matrix OLED (AMOLED). In the AMOLED, the brightness gray-scale performance is controlled by generally using thin film transistors (TFTs) together with capacitance storage signal. In the current OLED driving, a constant current is generally used for driving, and is defined as: I_{OLED}=k(V_{sg}−Vₜₕ)², wherein k is an intrinsic conductive factor, which is determined by characteristic of a thin film transistor itself, Vₜₕ is a threshold voltage of the thin film transistor, and V_{sg}=Vₛ−V_{g}. Vₛ generally equals to a power positive voltage provided by a power voltage supply.

In the prior art, factors of instability of panel product process, heat dissipation problem of the power voltage supply and instability of panel load may cause variation in the power positive voltage generated in the power voltage supply, a magnitude of current flowing in the OLED will be driven in this way, thereby resulting in a variation in a driving current of the OLED.

### SUMMARY

In order to solve the above problem in the prior art, an object of the present disclosure is to provide a display device, which allow a driving current to be constant when the power positive voltage is varied, and a method of driving the same.

According to an aspect of the present disclosure, there is provided a display device, which comprises a plurality of pixels each including a driving thin film transistor and an organic light emitting diode having an anode electrode is connected to a drain electrode of the driving thin film transistor, a power voltage supply supplying a power positive voltage to a source electrode of the driving thin film transistor, and supplying a power negative voltage to a cathode electrode of the organic light emitting diode, a voltage detector generating a compensation signal when detecting that the power positive voltage and a standard power positive voltage are different, a timing controller compensating a scan control signal and a data control signal generated therefrom based on the compensation signal, a scan driver generating a compensated scan voltage based on a compensated scan control signal and supplying the compensated scan voltage to the plurality of pixels and a data driver generating a compensated data voltage based on a compensated data control signal and supplying the compensated data voltage to the plurality of pixels, wherein the compensated scan voltage and the compensated data voltage allow a first driving current of the organic light emitting diode to be equal to a second driving current of the organic light emitting diode, the first driving current of the organic light emitting diode being a driving current of the organic light emitting diode when the power positive voltage and the standard power positive voltage are the same, the second driving current of the organic light emitting diode being a driving current of the organic light emitting diode when the power positive voltage and the standard power positive voltage are different.

Further, the voltage detector comprises a subtractor differencing a detected power positive voltage and the standard power positive voltage to calculate the compensation signal, and a signal amplifier amplifying the compensation signal.

Further, the voltage detector further comprises a noise filter performing noise filtering on the detected power positive voltage.

Further, the timing controller comprises a data processing module receiving image signals input externally and processing the image signal to be a scan control signal and a data control signal and a compensation module compensating the scan control signal and the data control signal processed by the data processing module based on the compensation signal.

Further, each of the plurality of pixels further includes a switching thin film transistor and a storage capacitor, wherein the switching thin film transistor has a drain electrode connected to a gate electrode of the driving thin film transistor, a gate electrode connected to the scan driver, and a source electrode connected to the data driver, and the storage capacitor is connected between the gate electrode and a source electrode of the driving thin film transistor.

According to another aspect of the present disclosure, there is provided a method of driving a display device, which comprises generating a compensation signal when detecting that a power positive voltage and a standard power positive voltage are different, compensating a scan control signal and a data control signal based on the compensation signal, generating a compensated scan voltage based on a compensated scan control signal and supplying the compensated scan voltage to pixels and generating a compensated data voltage according to a compensated data control signal and supplying the compensated data voltage to the pixels, wherein each of the pixels includes an organic light emitting diode, and the compensated scan voltage and the compensated data voltage allow a first driving current of the organic light emitting diode to be equal to a second driving current of the organic light emitting diode, the first driving current of the organic light emitting diode being a driving current of the organic light emitting diode when the power positive voltage and the standard power positive voltage are the same, the second driving current of the organic light emitting diode being a driving current of the organic light emitting diode when the power positive voltage and the standard power positive voltage are different.

Further, the generating of the compensation signal when detecting that the power positive voltage and the standard power positive voltage are different comprises differencing a detected power positive voltage and the standard power positive voltage to calculate the compensation signal and amplifying the compensation signal.

Further, the generating of the compensation signal when detecting that the power positive voltage and the standard power positive voltage are different further comprises performing noise filtering on the detected the power positive voltage.

Further, the compensating of the scan control signal and the data control signal based on the compensation signal comprises receiving image signals input externally and processing the image signals to be the scan control signal and the data control signal and compensating a processed scan control signal and a processed data control signal based on the compensation signal.

The present disclosure has the following advantageous effect: the display device and the method of diving the same of the present disclosure eliminates an effect to a display brightness of the organic light emitting diode due to the variation of the power positive voltage, thereby improving the display quality.

### BRIEF DESCRIPTION OF THE DRAWINGS

The above and/or other aspects, features and advantages of embodiments in the present disclosure will become more aparent from the following description, taken in conjunction with the accompanying drawings, in which:

FIG. 1 is a block diagram of a display device according to an embodiment of the present disclosure;

FIG. 2 is a circuit diagram of a pixel according to an embodiment of the present disclosure; and

FIG. 3 is a flow diagram of a method of driving the display device according to an embodiment of the present disclosure.

### DETAILED DESCRIPTION OF EXEMPLARY EMBODIMENTS

Embodiments of the present disclosure will be described in detail below by referring to the accompany drawings. However, the present disclosure can be implemented in numerous different forms, and the present disclosure may not be explained to be limited to the specific embodiments set forth herein. Rather, these embodiments are provided for explaining the principle and actual application of the present invention, thus other skilled in the art can understand various embodiments and amendments which are suitable for specific intended applications of the present invention.

In the drawings, thicknesses of layers and regions are exaggerated so as to clarify components. The same reference symbols may indicate the same components in the drawings and the description.

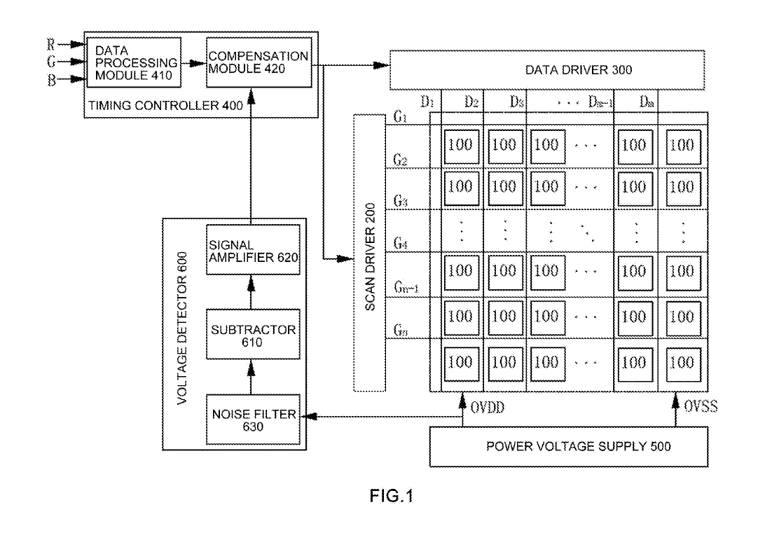

FIG. 1 is a block diagram of a display device according to an embodiment of the present disclosure.

Referring to FIG. 1, the display device according to the embodiment of the present disclosure includes a plurality of pixels 100, a scan driver 200, a data driver 300, a timing controller 400, a power voltage supply 500 and a voltage detector 600.

Particularly, the plurality of pixels 100 are connected with display signal lines. The display signal lines may include a plurality of scan lines G₁ to Gₙ for transmitting a scan voltage and a plurality of data lines D1 to Dm for transmitting a data voltage. The scan lines G₁ to Gₙ extend in a row direction and substantially parallel to each other, and the data lines D₁ to Dₘ extend in a column direction and substantially parallel to each other.

The scan driver 200 is connected to the scan lines G₁ to Gₙ, and applies the scan voltage to the scan lines G₁ to Gₙ. The scan voltage is supplied to the plurality of pixels 100 via the scan lines G₁ to Gₙ.

The data driver 300 is connected to the data lines D₁ to Dₘ, and applies the data voltage to the data lines D₁ to Dₘ. The data voltage is supplied to the plurality of pixels 100 via the data lines D₁ to Dₘ.

The timing controller 400 controls operations of the scan driver 200 and the data driver 300.

The timing controller 400 receives image signals (such as R, G and B signals) from an external graph controller. The timing controller 400 properly processes the image signals so as to generate a scan control signal and a data control signal. Then, the timing controller 400 transmits the scan control signal to the scan driver 200, and transmits the data control signal to the data driver 300.

The scan driver 200 generates the scan voltage in response to the scan control signal, and applies the scan voltage to the scan lines G₁ to Gₙ. The data driver 300 generates the data voltage in response to the data control signal, and applies the data voltage to the data lines D₁ to Dₘ.

The power voltage supply 500 generates a power positive voltage OVDD and a power negative voltage OVSS, and supplies the power positive voltage OVDD and the power negative voltage OVSS to the plurality of pixels 100.

The voltage detector 600 detects whether the power positive voltage OVDD supplied to the pixels 100 is the same as a standard power positive voltage or not. If they are the same, the voltage detector 600 does not generate a compensation signal. If they are different, the voltage detector 600 generates the compensation signal and supplies the compensation signal to the timing controller 400.

Further, the voltage detector 600 according to an embodiment of the present disclosure includes a subtractor 610, a signal amplifier 620 and a noise filter 630.

Particularly, the subtractor 610 is used for differencing a detected power positive voltage OVDD and the standard power positive voltage to calculate the compensation signal. Here, when the power positive voltage OVDD and the standard power positive voltage are the same, the compensation signal is equal to zero, in other words, the subtractor 610 does not generate the compensation signal. When the power positive voltage OVDD and the standard power positive voltage are different, the subtractor 610 differences the power positive voltage OVDD and the standard power positive voltage to generate the compensation signal.

The signal amplifier 620 amplifies the compensation signal. The noise filter 630 performs a noise filtering on the power positive voltage OVDD in advance before calculation of the subtractor 610 to the detected power positive voltage OVDD, so that noise in the power positive voltage OVDD can be removed. It should be understood that the noise filter 630 is a preferable embodiment, and as another embodiment of the present disclosure, the noise filter 630 may not exist.

The timing controller 400 receives the compensation signal, and compensates the scan control signal and the data control signal generated therefrom.

Further, the timing controller 400 according to an embodiment of the present disclosure includes a data processing module 410 and a compensation module 420.

Particularly, the data processing module 410 receives image signals (such as R, G and B signals) from an external graph controller (not shown). The data processing module 410 properly processes the image signals, thereby resulting in generating the scan control signal and the data control signal.

The compensation module receives the compensation signal supplied from the signal amplifier 620, and compensates the scan control signal and the data control signal processed by the data processing module 410 according to the compensation signal.

The scan driver 200 generates a compensated scan voltage according to a compensated scan control signal, and applies the compensated scan voltage to the scan lines G₁ to Gₙ.

The data driver 300 generates a compensated data voltage according to a compensated data control signal, and applies the compensated data voltage to the data lines D₁ to Dₘ.

The compensated scan voltage and the compensated data voltage are used to allow the brightness of the pixels maintain constant, which will be described below.

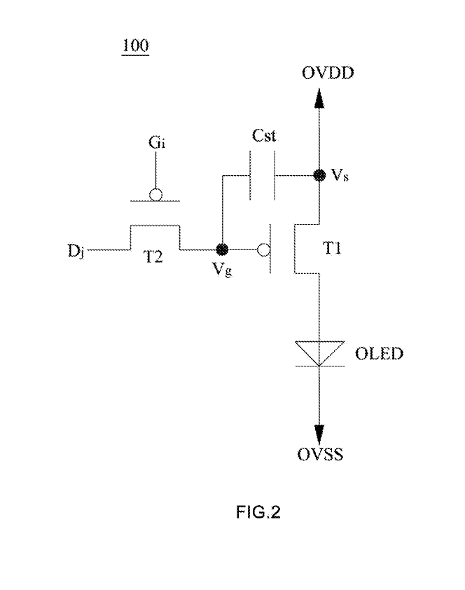

FIG. 2 is a circuit diagram of a pixel according to an embodiment of the present disclosure.

Referring to FIG. 2, each of the plurality of pixels 100 according to an embodiment of the present disclosure includes a driving thin film transistor T1, a switching thin film transistor T2, a storage capacitor Cst and an organic light emitting diode OLED.

The driving thin film transistor T1 has a drain electrode connected to an anode electrode of the organic light emitting diode OLED, a source electrode connected to the power voltage supply 500 to receive the power positive voltage OVDD, and a gate electrode connected to a drain of the switching thin film transistor T2, the organic light emitting diode OLED has an cathode electrode connected to the power voltage supply 500 to receive the power negative voltage OVSS, the switching thin film transistor T2 has a gate electrode connected to the scan lines Gi (1≤i≤n), and a source electrode connected to the data lines Dj (1≤j≤m), and the storage capacitor Cst is connected between the source and gate electrodes of the driving thin film transistor T1.

A driving current of the organic light emitting diode OLED is: I₁=k(V_{sg}−Vₜₕ)²=k(Vₛ−V_{R}−Vₜₕ)²=k(OVDD−V_{g}−Vₜₕ)², wherein k is an intrinsic conductive factor of the driving thin film transistor T1, which is determined by characteristic of the driving thin film transistor T1 itself, Vₜₕ is a threshold voltage of the driving thin film transistor T1, Vₛ is a source voltage of the driving thin film transistor T1, which equals to a power positive voltage OVDD, and V_{g} is a gate voltage of the driving thin film transistor T1, which is associated with the scan voltage and the data voltage.

When the voltage detector 600 detects that the power positive voltage OVDD is the same as the standard power positive voltage, the voltage detector 600 does not generate the compensation signal, and at this time, the driving current of the organic light emitting diode OLED is a first driving current. Here, the standard power positive voltage refers to a voltage which allow the organic light emitting diode OLED to be normally operated and the driving current to be constant.

When the voltage detector 600 detects that the power positive voltage OVDD is different from the standard power positive voltage, the voltage detector 600 generates the compensation signal, and at this time, the driving current of the organic light emitting diode OLED is a second driving current. The first driving current equals to the second driving current, which is specially described below.

When the voltage detector 600 detects that the power positive voltage OVDD is greater than the standard power positive voltage, the voltage detector 600 generates a first compensation signal, and supplies the first compensation signal to the timing controller 400. The timing controller 400 receives the first compensation signal, and compensates the scan control signal and the data control signal generated therefrom according to the first compensation signal. The scan driver 200 generates a first compensated scan voltage according to the compensated scan control signal, and applies the first compensated scan voltage to the scan lines G₁ to Gₙ. The data driver 300 generates a first compensated data voltage according to the compensated data control signal, and applies the first compensated data voltage to the data lines D₁ to Dₘ. The gate voltage V_{g} of the driving thin film transistor T1 is increased by the first compensation scan voltage and the first compensated data voltage, such that an increased value of the gate voltage V_{g} offsets an increased value of the power positive voltage OVDD, thereby maintaining the driving current of the organic light emitting diode OLED to be constant.

When the voltage detector 600 detects that the power positive voltage OVDD is lower than the standard power positive voltage, the voltage detector 600 generates a second compensation signal, and supplies the second compensation signal to the timing controller 400. The timing controller 400 receives the second compensation signal, and compensates the scan control signal and the data control signal generated therefrom according to the second compensation signal. The scan driver 200 generates a second compensated scan voltage according to the compensated scan control signal, and applies the second compensated scan voltage to the scan lines G₁ to Gₙ. The data driver 300 generates a second compensated data voltage according to the compensated data control signal, and applies the second compensated data voltage to the data lines D₁ to Dₘ. The gate voltage V_{g} of the driving thin film transistor T1 is decreased by the second compensation scan voltage and the second compensated data voltage, such that a decreased value of the gate voltage V_{g} offsets a decreased value of the power positive voltage OVDD, thereby maintaining the driving current of the organic light emitting diode OLED to be constant.

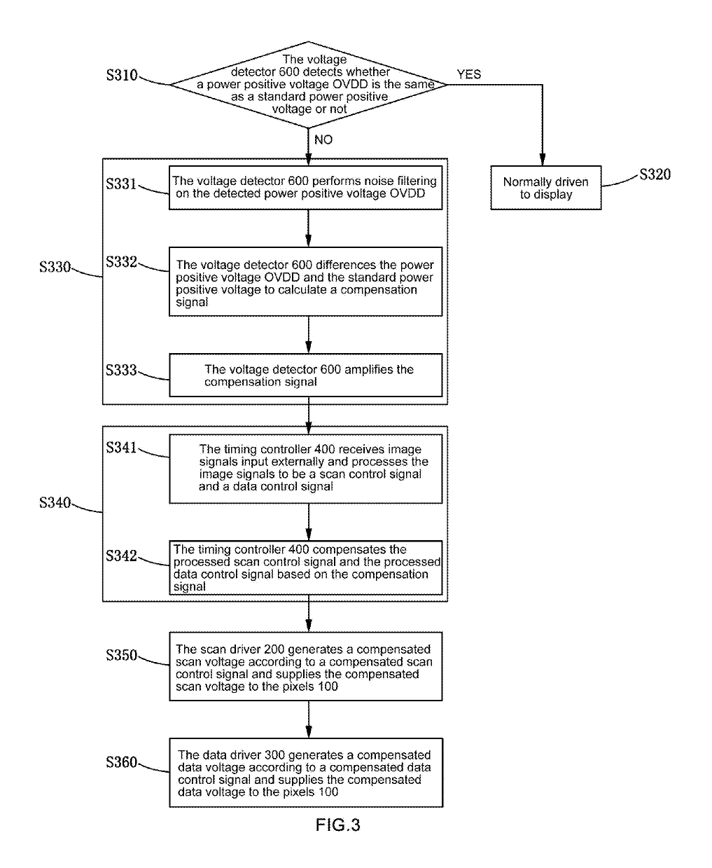

FIG. 3 is a flow diagram of a method of driving the display device according to an embodiment of the present disclosure.

Referring to FIG. 3, the method of driving the display device according to the embodiment of the present disclosure includes steps 310 to 360.

Referring to FIGS. 1 to 3, in step S310, the voltage detector 600 detects whether a power positive voltage OVDD is the same as a standard power positive voltage or not. If they are the same, step S320 is performed, and if they are different, steps S330 to S360 are performed.

In step S320, the display device is normally driven to display.

In step S330, the voltage detector 600 differences the power positive voltage OVDD and the standard power positive voltage to calculate a compensation signal.

A method of realizing step S330 includes steps S331-333.

In step S331, the voltage detector 600 performs noise filtering on the detected power positive voltage OVDD. As another implementation of the present disclosure, the step may be omitted.

In step S332, the voltage detector 600 differences the power positive voltage OVDD and the standard power positive voltage to calculate a compensation signal.

In step S333, the voltage detector 600 amplifies the compensation signal.

In step S340, the timing controller 400 compensates the scan control signal and the data control signal based on the compensation signal.

A method of realizing step S340 includes steps S341-S343.

In step S341, the timing controller 400 receives image signals input externally and processes the image signals to be a scan control signal and a data control signal.

In step S342, the timing controller 400 compensates the processed scan control signal and the processed data control signal based on the compensation signal.

In step S350, the scan driver 200 generates a compensated scan voltage according to a compensated scan control signal and supplies the compensated scan voltage to the pixels 100.

In step S360, the data driver 300 generates a compensated data voltage according to a compensated data control signal and supplies the compensated data voltage to the pixels 100.

The compensated scan voltage in step S350 and the compensated data voltage in step S360 allow the driving current of the organic light emitting diode OLED when the power positive voltage OVDD and the standard power positive voltage are different to be equal to the driving current of the organic light emitting diode OLED when the power positive voltage OVDD and the standard power positive voltage are the same, such that the driving current of the organic light emitting diode OLED is constant and thus the brightness of light emission is constant.

To sum up, the display device and the method of driving the same according to an embodiment of the present disclosure eliminates an affect to a display brightness of the organic light emitting diode OLED due to the variation of the power positive voltage OVDD, thereby improving the display quality.

Although the present invention is shown and described with reference to the special embodiment, while those skilled in the art will understand: various changes in form and details may be made therein without departing from the spirit and scope of the invention as defined by the appended claims and its equivalents.

What is claimed:

1. A display device, comprising:
a plurality of pixels each including a driving thin film transistor and an organic light emitting diode having an anode electrode is connected to a drain electrode of the driving thin film transistor;
a power voltage supply supplying a power positive voltage to a source electrode of the driving thin film transistor, and supplying a power negative voltage to a cathode electrode of the organic light emitting diode;
a voltage detector generating a compensation signal when detecting that the power positive voltage and a standard power positive voltage are different;
a timing controller compensating a scan control signal and a data control signal generated therefrom based on the compensation signal;
a scan driver generating a compensated scan voltage based on a compensated scan control signal and supplying the compensated scan voltage to the plurality of pixels; and
a data driver generating a compensated data voltage based on a compensated data control signal and supplying the compensated data voltage to the plurality of pixels,
wherein the compensated scan voltage and the compensated data voltage allow a first driving current of the organic light emitting diode to be equal to a second driving current of the organic light emitting diode, the first driving current of the organic light emitting diode being a driving current of the organic light emitting diode when the power positive voltage and the standard power positive voltage are the same, the second driving current of the organic light emitting diode being a driving current of the organic light emitting diode when the power positive voltage and the standard power positive voltage are different.

2. The display device of claim 1, wherein the voltage detector comprises:
a subtractor differencing a detected power positive voltage and the standard power positive voltage to calculate the compensation signal; and
a signal amplifier amplifying the compensation signal.

3. The display device of claim 2, wherein the voltage detector further comprises:
a noise filter performing noise filtering on the detected power positive voltage.

4. The display device of claim 1, wherein the timing controller comprises:
a data processing module receiving image signals input externally and processing the image signal to be a scan control signal and a data control signal; and
a compensation module compensating the scan control signal and the data control signal processed by the data processing module based on the compensation signal.

5. The display device of claim 1, wherein each of the plurality of pixels further includes a switching thin film transistor and a storage capacitor,
wherein the switching thin film transistor has a drain electrode connected to a gate electrode of the driving thin film transistor, a gate electrode connected to the scan driver, and a source electrode connected to the data driver, and the storage capacitor is connected between the gate electrode and a source electrode of the driving thin film transistor.

6. The display device of claim 2, wherein each of the plurality of pixels further includes a switching thin film transistor and a storage capacitor,
wherein the switching thin film transistor has a drain electrode connected to a gate electrode of the driving thin film transistor, a gate electrode connected to the scan driver, and a source electrode connected to the data driver, and the storage capacitor is connected between the gate electrode and a source electrode of the driving thin film transistor.

7. The display device of claim 3, wherein each of the plurality of pixels further includes a switching thin film transistor and a storage capacitor,
wherein the switching thin film transistor has a drain electrode connected to a gate electrode of the driving thin film transistor, a gate electrode connected to the scan driver, and a source electrode connected to the data driver, and the storage capacitor is connected between the gate electrode and a source electrode of the driving thin film transistor.

8. The display device of claim 4, wherein each of the plurality of pixels further includes a switching thin film transistor and a storage capacitor,
wherein the switching thin film transistor has a drain electrode connected to a gate electrode of the driving thin film transistor, a gate electrode connected to the scan driver, and a source electrode connected to the data driver, and the storage capacitor is connected between the gate electrode and a source electrode of the driving thin film transistor.

9. A method of driving a display device, comprising:
generating a compensation signal when detecting that a power positive voltage and a standard power positive voltage are different;
compensating a scan control signal and a data control signal based on the compensation signal;
generating a compensated scan voltage based on a compensated scan control signal and supplying the compensated scan voltage to pixels; and
generating a compensated data voltage according to a compensated data control signal and supplying the compensated data voltage to the pixels,
wherein each of the pixels includes an organic light emitting diode, and the compensated scan voltage and the compensated data voltage allow a first driving current of the organic light emitting diode to be equal to a second driving current of the organic light emitting diode, the first driving current of the organic light emitting diode being a driving current of the organic light emitting diode when the power positive voltage and the standard power positive voltage are the same, the second driving current of the organic light emitting diode being a driving current of the organic light emitting diode when the power positive voltage and the standard power positive voltage are different.

10. The method of claim 9, wherein the generating of the compensation signal when detecting that the power positive voltage and the standard power positive voltage are different comprises:
differencing a detected power positive voltage and the standard power positive voltage to calculate the compensation signal; and
amplifying the compensation signal.

11. The method of claim 10, wherein the generating of the compensation signal when detecting that the power positive voltage and the standard power positive voltage are different further comprises:
performing noise filtering on the detected the power positive voltage.

12. The method of claim 9, wherein the compensating of the scan control signal and the data control signal based on the compensation signal comprises:
receiving image signals input externally and processing the image signals to be the scan control signal and the data control signal; and
compensating a processed scan control signal and a processed data control signal based on the compensation signal.
